(19) United States
(12) Patent Application Publication
(10) Pub. No.: US 2026/0147954 A1
(43) Pub. Date: May 28, 2026

(54) CHARACTERIZATION METHOD FOR INFLUENCE OF CORROSION DEGREE ON INTERFACIAL BONDING PERFORMANCE BETWEEN STEEL FIBER AND CONCRETE

(71) Applicant: SHENZHEN UNIVERSITY, Shenzhen (CN)

(72) Inventors: Dapeng ZHENG, Shenzhen (CN); Hongzhi CUI, Shenzhen (CN); Jiuwen ZHU, Shenzhen (CN); Peiyun ZHANG, Shenzhen (CN); Wenqian DU, Shenzhen (CN); Xiangpeng CAO, Shenzhen (CN); Xiaohua BAO, Shenzhen (CN)

(21) Appl. No.: 19/339,924

(22) Filed: Sep. 25, 2025

(30) Foreign Application Priority Data
Nov. 22, 2024 (CN) 202411682572.2

(51) Int. Cl. G06F 30/17

(52) U.S. Cl. CPC G06F 30/17

(57) ABSTRACT

Provided is a characterization method for influence of a corrosion degree on interfacial bonding performance between a steel fiber and a concrete. The characterization method solves the technical problem that the conventional testing methods require significant time and cost investments, and are difficult to comprehensively and accurately reflect the complicated influence of corrosion on the interfacial bonding performance. The characterization method includes: conducting a preset acid-washing operation for steel fibers undergoing an uniaxial tensile test one by one; based on a mass change of each steel fiber before and after the preset acid-washing operation, calculating mass loss rates of steel fibers with different corrosion degrees one by one; fitting interfacial bonding strength data corresponding to the different corrosion degrees by a preset statistical analysis method to produce a mathematical expression between an interfacial bonding strength and a corrosion degree.

### CROSS REFERENCE TO RELATED APPLICATION

This patent application claims the benefit and priority of Chinese Patent Application No. 2024116825722, filed with the China National Intellectual Property Administration on Nov. 22, 2024, the disclosure of which is incorporated by reference herein in its entirety as part of the present application.

### TECHNICAL FIELD

The present disclosure relates to the technical field of performance research for steel fiber-reinforced concrete materials, and in particular relates to a characterization method for influence of a corrosion degree on interfacial bonding performance between a steel fiber and a concrete.

### BACKGROUND

In the field of construction engineering, steel fiber-reinforced concrete is widely used due to its outstanding mechanical properties. Steel fiber-reinforced concrete can significantly improve the tensile strength, flexural strength, and toughness of concrete, thereby enhancing the structural durability and reliability. However, in practical service environments, steel fiber-reinforced concrete structures often face various challenges, among which the corrosion of steel fibers is particularly prominent. The corrosion of steel fibers not only degrades the mechanical properties of steel fibers themselves, but also remarkably compromises the interfacial bonding performance between steel fibers and concrete, thereby jeopardizing the safety and stability of the overall structure.

Currently, the research on the influence of a corrosion degree on the interfacial bonding performance between steel fibers and concrete primarily relies on the conventional testing methods, such as pull-out tests, shear tests, electrochemical tests, and microstructure observation.

The conventional testing methods require significant time and cost investments, and are still difficult to comprehensively and accurately reflect the complicated influence of corrosion on the interfacial bonding performance.

### SUMMARY

To comprehensively evaluate the influence of corrosion on the interfacial bonding performance between steel fibers and concrete in various aspects and enhance the safety and durability of steel fiber-reinforced concrete structures in practical applications, the present application proposes a characterization method and system for influence of a corrosion degree on interfacial bonding performance between a steel fiber and a concrete.

In a first aspect, the present application provides a characterization method for influence of a corrosion degree on interfacial bonding performance between a steel fiber and a concrete, which adopts the following technical solutions:

The characterization method for influence of a corrosion degree on interfacial bonding performance between a steel fiber and a concrete includes:
for each of a preset number of semi-dogbone-shaped samples, conducting concrete pouring with a single steel fiber embedded at a preset embedding depth, and curing under preset curing conditions;
subjecting an obtained cured specimen to electrochemical corrosion tests matched with predetermined different steel fiber corrosion degrees to produce specimens with different corrosion degrees, where each specimen is a semi-dogbone-shaped sample with a single steel fiber embedded;
conducting a preset uniaxial tensile test for the specimens with the different corrosion degrees to obtain a load change of each steel fiber during a pull-out process, and analyzing interfacial bonding strengths between steel fibers with different corrosion degrees and concretes; and conducting a preset acid-washing operation for steel fibers undergoing the preset uniaxial tensile test one by one, and based on a mass change of each steel fiber before and after the preset acid-washing operation, calculating mass loss rates of the steel fibers with the different corrosion degrees one by one, where a mass loss rate of a steel fiber is defined as corrosion degree data of the steel fiber; and
fitting interfacial bonding strength data corresponding to the different corrosion degrees by a preset statistical analysis method to produce a mathematical expression between an interfacial bonding strength and a corrosion degree.

Through the above technical solution, the manufacturing and curing conditions for a specimen can be accurately controlled to ensure the experimental accuracy. The acquisition of specimens with different corrosion degrees through electrochemical corrosion tests can substantially reflect the actual conditions. A load change and an interfacial bonding strength are determined by the uniaxial tensile test to quantify the bonding performance. A mass loss rate is calculated to define a corrosion degree, thereby providing specific data for the research. The mathematical expression produced after the fitting clearly illustrates the relationship between a corrosion degree and interfacial bonding performance, and serves as a robust tool for evaluating and predicting the performance of a concrete structure under varying corrosion conditions. Thus, the mathematical expression facilitates the targeted application of protective measures, thereby guaranteeing the long-term stability and safety of a steel fiber-reinforced concrete structure.

Optionally, the characterization method further includes steps in parallel with the fitting interfacial bonding strength data corresponding to the different corrosion degrees by a preset statistical analysis method to produce a mathematical expression between an interfacial bonding strength and a corrosion degree, where the steps are specifically as follows:
subtracting a corrosion pit volume from a steel fiber through a Boolean operation to produce a steel fiber model with regular corrosion pits, where irregular corrosion pits on a steel fiber are defined as semi-ellipsoidal regular corrosion pits, and corrosion pits are distributed in a length direction of the steel fiber under a same rule;
based on corrosion degree data of a steel fiber, determining a number and size of corrosion pits by a parametric modeling method, where a plurality of corrosion pits are uniformly distributed in a length direction of the steel fiber;
according to a functional relationship between a preset corrosion degree and mechanical property parameters of a steel fiber, correcting a stress-strain constitutive relationship for an uncorroded steel fiber;
according to the uniaxial tensile test, measuring relative slips between a steel fiber and a concrete under different pull-out forces, and establishing a relationship between a bonding force and a slip to produce a bond-slip constitutive model; and multiplying the bond-slip constitutive model by a preset corrosion degree reduction factor to quantitatively determine influence of a corrosion degree on bonding performance between the steel fiber and the concrete;
based on a measured dimension of a specimen, creating a three-dimensional geometric model for the specimen with finite element analysis software;
based on a geometric shape of a regular steel fiber and an assumption of semi-ellipsoidal corrosion pits, creating a steel fiber model with corrosion pits, and setting material properties for both a concrete and a steel fiber;
defining material properties for a bonding element, and arranging the bonding element at an interface between a steel fiber and a concrete with a correct direction and position of the bonding element guaranteed; and according to the determined mathematical expression between an interfacial bonding strength and a corrosion degree, inputting corresponding parameters into the bonding element to simulate a bonding failure and a friction slip at the interface during a pull-out process; and
based on preset solving parameters for numerical simulation, running the numerical simulation; analyzing solving results, and extracting key mechanical property indexes; and compiling results under the different corrosion degrees, and plotting relevant views for visual presentation.

In the above technical solution, the construction of a regular corrosion pit model and the determination of a number and size of corrosion pits can accurately simulate the actual corrosion situation. The correction of the stress-strain constitutive relationship for steel fibers and the establishment of the bond-slip constitutive model enable the quantitative analysis for the influence of corrosion on bonding performance. Creating the model with finite element analysis software, setting material properties, and inputting parameters based on the mathematical expression to simulate a bonding failure and a friction slip enhance the scientific rigor of analysis. The running of the numerical simulation and the visual presentation of results facilitate the intuitive understanding of mechanical property indexes under different corrosion degrees, thereby providing a comprehensive and efficient method for evaluating the interfacial bonding performance between steel fibers and concrete and supporting the improved prediction and optimization of structural durability in practical projects.

Optionally, the characterization method further includes steps in parallel with the fitting interfacial bonding strength data corresponding to the different corrosion degrees by a preset statistical analysis method to produce a mathematical expression between an interfacial bonding strength and a corrosion degree, where the steps are specifically as follows:
scanning to acquire surface morphology data of a corroded steel fiber, and subjecting the surface morphology data of the corroded steel fiber to automatic analysis and feature extraction with a preset image recognition algorithm;
importing geometric morphology data of the corroded steel fiber that is extracted by the preset image recognition algorithm into Matlab software for processing, and creating a point cloud file with the Matlab software, that is, representing a surface morphology of the corroded steel fiber as a series of point coordinates;
importing the point cloud file generated by the Matlab software into three-dimensional scanning data processing software for envelope processing and noise reduction, and converting processed point cloud data into a high-accuracy curved surface to produce geometric data of the corroded steel fiber;
meshing the corroded steel fiber with Hypermesh software according to a preset meshing method, and importing a mesh model generated by the Hypermesh software into Abaqus software to produce a numerical model for the corroded steel fiber; and defining material properties, boundary conditions, and loading conditions for the corroded steel fiber;
based on a measured dimension of a semi-dogbone-shaped sample with a single steel fiber and an accurate morphology set for corroded steel fibers, establishing a single-fiber concrete unilateral pull-out numerical model within a monitoring range of an extensometer, and defining material properties, boundary conditions, and loading conditions for a concrete; and
solving an established numerical model with the Abaqus software, analyzing solving results, and extracting key mechanical property indexes; and compiling results under the different corrosion degrees, and plotting relevant views for visual presentation.

In the above technical solution, surface morphology data of a corroded steel fiber is extracted through scanning and image recognition, which can accurately reflect the actual corrosion conditions. The generation of high-accuracy geometric data through software processing, the meshing, and the establishment of the numerical model can accurately simulate the single-fiber concrete unilateral pull-out process. The definition for material properties, etc. make the model more in line with the actual conditions. The solving with the Abaqus software and the visual presentation of results facilitate the intuitive understanding of mechanical property indexes under different corrosion degrees. This technical solution provides an efficient and accurate method for investigating the influence of a corrosion degree on the interfacial bonding performance between steel fibers and concrete, is conducive to the in-depth comprehension of the influence of corrosion, and provides a scientific basis and technical support for improving the durability of concrete structures in projects.

Optionally, the subjecting an obtained cured specimen to electrochemical corrosion tests matched with predetermined different steel fiber corrosion degrees to produce specimens with different corrosion degrees includes:
soaking all cured specimens in a salt solution prepared in advance, connecting a positive electrode of a direct-current power supply to a steel fiber, and connecting a negative electrode of the direct-current power supply to an auxiliary electrode;
according to Faraday's law of electrolysis, calculating desired electricity quantities based on a surface area of a steel fiber and different expected corrosion degrees to determine combinations of current intensities and electrification times as corrosion conditions for the different expected corrosion degrees; and
testing each specimen under the corrosion conditions for the different expected corrosion degrees, and stopping the testing after a preset condition is met to obtain the specimens with the different corrosion degrees.

In the above technical solution, the actual corrosion environment is simulated through salt solution soaking and electrode connection. The corrosion conditions are determined based on the Faraday's law of electrolysis to accurately control the different expected corrosion degrees. Each specimen is tested individually to produce specimens with varying corrosion degrees. This technical solution provides abundant samples for studying the influence of corrosion on the interfacial bonding performance between steel fibers and concrete, contributes to the in-depth comprehension of change laws, provides a basis for improving the durability of concrete structures, and offers an effective method and data support for solving the corrosion issues in projects.

Optionally, the characterization method further includes steps between the testing each specimen under the corrosion conditions for the different expected corrosion degrees and the stopping the testing after a preset condition is met, where the steps are specifically as follows:
during a corrosion process, starting an electrochemical impedance spectroscopy monitoring device to monitor and acquire electrochemical impedance spectroscopy data, and extracting resistance and capacitance parameters from the electrochemical impedance spectroscopy data; and synchronously starting an electrochemical noise monitoring device to acquire electrochemical noise data, and extracting a noise amplitude from the electrochemical noise data;
calculating comprehensive corrosion index values at different time points according to a preset comprehensive corrosion index calculation method, and plotting a change curve of a comprehensive corrosion index over time;
according to the change curve of a comprehensive corrosion index over time, determining a comprehensive corrosion index change efficiency; and
determining an adjustment plan for corrosion conditions of an expected corrosion degree based on a correspondence between a range of the comprehensive corrosion index change efficiency and the adjustment plan for the corrosion conditions of the expected corrosion degree, and implementing the adjustment plan for the corrosion conditions of the expected corrosion degree.

In the above technical solution, during a corrosion process, parameters can be monitored and extracted in real time, and comprehensive corrosion indexes are calculated, such that the change curve is plotted to analyze the change efficiency, thereby adjusting the corrosion conditions. As a result, it can be accurately controlled to achieve specimens with different expected corrosion degrees, thereby providing accurate samples for the research. This technical solution contributes to the in-depth understanding of a corrosion process, provides a reliable data support for evaluating the influence of corrosion on the interfacial bonding performance between steel fibers and concrete, improves the scientific rigor and accuracy of research, and offers a prominent method for addressing the corrosion issues in practical engineering.

Optionally, the conducting a preset uniaxial tensile test for the specimens with the different corrosion degrees to obtain a load change of each steel fiber during a pull-out process, and analyzing interfacial bonding strengths between steel fibers with different corrosion degrees and concretes includes:
arranging a semi-dogbone-shaped sample in a fixture of an electronic universal testing machine;
starting the electronic universal testing machine, conducting a pull-out test under crosshead displacement control, and synchronously acquiring experimental data, where the crosshead displacement control refers to achieving loading of the semi-dogbone-shaped sample by controlling a crosshead movement speed of the electronic universal testing machine, and the experimental data includes force, displacement, and deformation data;
plotting a pull-out force-displacement curve according to force and displacement data in the experimental data, and based on the pull-out force-displacement curve, determining a peak pull-out force, which is a maximum force withstood by the semi-dogbone-shaped sample during the pull-out test; and based on a geometric dimension of the semi-dogbone-shaped sample and an embedding depth parameter of a steel fiber, calculating a contact area between the steel fiber and a concrete; and
dividing the peak pull-out force by the contact area to calculate an interfacial bonding strength.

In the above technical solution, a specimen is accurately arranged, a pull-out test is conducted under crosshead displacement control, and data is synchronously acquired. A pull-out force-displacement curve is plotted to determine a peak pull-out force, and a contact area is calculated based on a geometric dimension, so as to calculate an interfacial bonding strength. This approach is accurate and reliable, and can effectively analyze the interfacial bonding performance between steel fibers with varying corrosion degrees and concretes. Thus, this approach provides a scientific basis for structural durability assessment, and is beneficial for the application of targeted measures in projects to enhance the safety and reliability of concrete structures.

Optionally, the conducting a preset acid-washing operation for steel fibers undergoing the preset uniaxial tensile test one by one, and based on a mass change of each steel fiber before and after the preset acid-washing operation, calculating mass loss rates of the steel fibers with the different corrosion degrees one by one includes: after the preset uniaxial tensile test, taking each steel fiber out, and acid-washing the steel fiber using a hydrochloric acid solution in combination with a corrosion inhibitor to dissolve a corrosion layer on a surface to produce an acid-washed steel fiber; fully rinsing the acid-washed steel fiber with deionized water and absolute ethanol to produce a rinsed steel fiber, oven-drying the rinsed steel fiber to produce a dry steel fiber, and weighing the dry steel fiber with an electronic balance; and comparing a post-test mass and a pre-test mass of each steel fiber to calculate a corrosion degree of each steel fiber, where the corrosion degree is expressed as a mass loss rate, that is, the corrosion degree=(pre-test mass-post-test mass)/pre-test mass×100%.

In the above technical solution, a corrosion layer is removed through acid-washing, and a post-test mass and a pre-test mass of a steel fiber are accurately measured. A mass loss rate is calculated to reflect a corrosion degree, which is simple and intuitive. Varying corrosion degrees can be effectively quantified to provide detailed data for investigating the influence of corrosion on the interfacial bonding performance between a steel fiber and a concrete. This technical solution contributes to the in-depth understanding of the influence of corrosion, provides a scientific basis for improving the durability of concrete structures, and facilitates the implementation of targeted measures in projects to ensure the structural safety and reliability.

Optionally, the characterization method further includes steps in parallel with the conducting a preset acid-washing operation for steel fibers undergoing the preset uniaxial tensile test one by one, and based on a mass change of each steel fiber before and after the preset acid-washing operation, calculating mass loss rates of the steel fibers with the different corrosion degrees one by one, where the steps are specifically as follows:
synchronously scanning a steel fiber by a micro X-ray computed tomography (μ-XCT) device at different angles to acquire scanning data at the different angles, and reconstructing a three-dimensional image of the steel fiber; analyzing a gray-scale distribution of the three-dimensional image acquired by μ-XCT scanning, and distinguishing among a concrete, the steel fiber, and a corrosion product; extracting surface morphology features of the steel fiber by a morphological analysis method; and integrating results of gray-scale and morphological analysis for quantification to obtain a corrosion degree of the steel fiber;
comparing the corrosion degree determined based on μ-XCT scanning results and the corrosion degree determined based on the preset acid-washing operation, and if a comparison result falls within a preset difference range, taking an average of the corrosion degrees for the steel fiber that are determined by the above two modes as a corrosion degree of the steel fiber confirmed this time; and
if the comparison result is beyond the preset difference range, transmitting condition information with a large error to a terminal held by a relevant person in charge.

In the above technical solution, a steel fiber is scanned by the μ-XCT device to acquire a three-dimensional image, and a corrosion degree is quantified accordingly and compared with the corrosion degree determined based on acid-washing. If a comparison result falls within the preset difference range, an average is taken, which can improve the accuracy of corrosion degree determination. If the comparison result is beyond the preset difference range, information is transmitted for timely handling.

Optionally, the characterization method further includes steps in parallel with the comparing the corrosion degree determined based on μ-XCT scanning results and the corrosion degree determined based on the preset acid-washing operation, and if a comparison result falls within a preset difference range, taking an average of the corrosion degrees for the steel fiber that are determined by the above two modes as a corrosion degree of the steel fiber confirmed this time, where the steps are specifically as follows:
acquiring a mass loss rate after the preset acid-washing operation, image feature parameters acquired by the μ-XCT scanning, and pull-out load data of the preset uniaxial tensile test, and determining a corrosion degree of a steel fiber as a dependent variable; and
using a multivariable linear regression model to establish a relationship model between the corrosion degree of the steel fiber as the dependent variable and the mass loss rate after the preset acid-washing operation, the image feature parameters acquired by the μ-XCT scanning, and the pull-out load data of the preset uniaxial tensile test as independent variables.

In the above technical solution, various types of data are acquired, and a relationship between a corrosion degree and various variables is established with a multivariable linear regression model. A corrosion degree of a steel fiber can be accurately assessed by integrating various factors, thereby providing a scientific approach for studying the influence of corrosion. This technical solution is conducive to the in-depth comprehension of a correlation between various factors and corrosion, proposes a basis for improving the durability of concrete structures, makes the analysis of interfacial bonding performance between a steel fiber and a concrete comprehensive and reliable, and offers an effective solution for solving the corrosion problem in engineering.

In a second aspect, the present application provides a characterization system for influence of a corrosion degree on interfacial bonding performance between a steel fiber and a concrete, which adopts the following technical solution:

The characterization system for influence of a corrosion degree on interfacial bonding performance between a steel fiber and a concrete includes a memory, a processor, and a program that is stored in the memory and is executable by the processor, where when loaded and executed by the processor, the program is able to implement the characterization method for influence of a corrosion degree on interfacial bonding performance between a steel fiber and a concrete described in the first aspect.

In summary, the present application has the following beneficial technical effects:

1. In the present disclosure, the corrosion process of steel fibers includes the three stages of corrosion initiation, free expansion, and cracking. The corrosion-induced degradation process is similar to the natural corrosion of steel fibers in concrete. Thus, the corrosion-induced degradation process can accurately reflect the influence of a corrosion degree on the interfacial bonding performance between steel fibers and concrete, and improve the accuracy of corrosion risk assessment.

2. The present disclosure adopts the additional application of a current to rapidly achieve the corrosion of steel fibers in concrete, which can significantly reduce the time consumption compared to the natural corrosion, thereby lowering the time cost.

3. In the present disclosure, a solution for soaking a specimen and a concentration of the solution can be determined based an environment to which a concrete member is exposed. Additionally, a concrete age can be adjusted based on engineering requirements to fit the actual engineering situation. In this way, the influence of a corrosion degree on the interfacial bonding performance between steel fibers and concrete under various operating conditions can be accurately reflected, and the performance evolution constructed during a service process can be evaluated, thereby providing a reliable basis for repair, reinforcement, or demolition.

4. The establishment of the steel fiber pull-out numerical model in the present disclosure can set different corrosion degrees for steel fibers and varying microstructures for an interface between a steel fiber and a substrate to allow the rapid simulation and calculation of impacts of different corrosion degrees on the interfacial bonding performance between the steel fiber and the substrate. As a result, a repair and reinforcement plan for a component during an operation phase can be timely formulated, thereby ensuring the safe service of the component.

### BRIEF DESCRIPTION OF THE DRAWINGS

FIG. 1 is a schematic flow chart of a characterization method for influence of a corrosion degree on interfacial bonding performance between a steel fiber and a concrete in an embodiment of the present application;

FIG. 2 is a schematic flow chart of steps in parallel with the fitting interfacial bonding strength data corresponding to the different corrosion degrees by a preset statistical analysis method to produce a mathematical expression between an interfacial bonding strength and a corrosion degree in another embodiment of the present application;

FIG. 3 is a schematic flow chart of steps in parallel with the fitting interfacial bonding strength data corresponding to the different corrosion degrees by a preset statistical analysis method to produce a mathematical expression between an interfacial bonding strength and a corrosion degree in another embodiment of the present application;

FIG. 4 is a schematic flow chart of subjecting an obtained cured specimen to electrochemical corrosion tests matched with predetermined different steel fiber corrosion degrees to produce specimens with different corrosion degrees in another embodiment of the present application;

FIG. 5 is a schematic diagram of an accelerated corrosion process of a semi-dogbone-shaped sample with a single steel fiber; and

FIG. 6 is a schematic diagram of pull-out load curves of semi-dogbone-shaped samples each with a single steel fiber.

### DETAILED DESCRIPTION OF THE EMBODIMENTS

The present application will be further described in detail below with reference to the accompanying drawings.

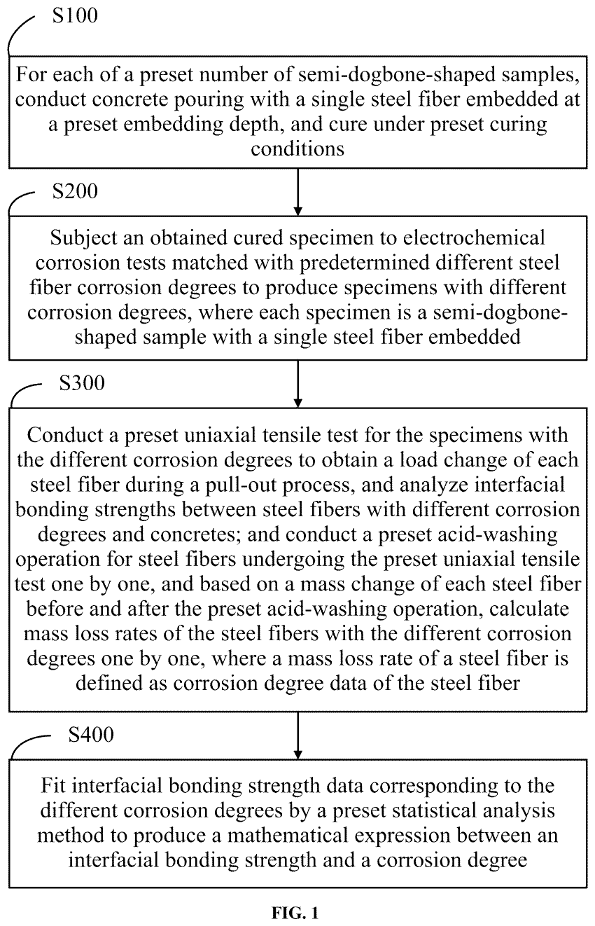

As shown in FIG. 1, the present application discloses a characterization method for influence of a corrosion degree on interfacial bonding performance between a steel fiber and a concrete, including:

S100: For each of a preset number of semi-dogbone-shaped samples, concrete pouring is conducted with a single steel fiber embedded at a preset embedding depth, and curing is conducted under preset curing conditions.

The semi-dogbone-shaped samples are concrete specimens with a specific shape resembling a part of a dogbone shape. The semi-dogbone-shaped samples are produced through pouring in a customized mold. For example, a high-strength plastic mold with a desired dimension and shape is adopted, a concrete is then poured into the high-strength plastic mold, and a single steel fiber is embedded at a preset embedding depth.

The preset embedding depth is a specific depth for embedding a steel fiber into a concrete specimen. An appropriate embedding depth can be determined through a theoretical calculation, a preliminary experiment, or referring to a relevant standard. For example, through theoretical analysis and a preliminary experiment, an embedding depth is determined to be one-third of a thickness of a specimen.

The preset curing conditions mean that, in order to make a concrete specimen have a specified strength and specified properties, the curing needs to be conducted under specific environmental conditions. For example, in a standard curing room, the curing is conducted at a temperature of 20±2° C. and a relative humidity of 95% or more for a specified period of time, such as 28 d.

More specifically, the above step can be further divided into the following three parts: cleaning steel fibers, placing the steel fibers, and pouring the semi-dogbone-shaped samples.

Specific steps for cleaning steel fibers are as follows: A suitable number of steel fibers with a standard shape and without corrosion on a surface are taken, cleaned with each of distilled water and absolute ethanol for 5 min in an ultrasonic cleaning machine to remove any adhesive and oil stains on the surface, wipe-dried, numbered for easy identification, and weighed one by one (accurate to 0.0001 g) to obtain an initial weight of each steel fiber, which is a weight before acid-washing.

A specific step for placing the steel fibers are as follows: A cleaned single steel fiber is inserted into a middle hole of a polyvinyl chloride (PVC) sheet to achieve a depth adjustment. In addition, an inclination angle of a fiber can be set according to a direction of loading. After an embedding depth is set, a steel fiber is fixed with a foam board to prevent the movement of the steel fiber during pouring and compaction processes, so as to maintain an angle and an embedding depth of the steel fiber in a specimen.

Specific steps for pouring the semi-dogbone-shaped samples are as follows: A cement material, a sand, and an additive are weighed according to a specified water-to-cement ratio and cement-to-sand ratio, then pre-mixed for 20 s to 30 s in a mixer at a low speed, and then mixed at a high speed for 3 min to 5 min. After the mixing is completed, a resulting slurry is poured into a mold with a steel fiber embedded. The mold is vibrated on a vibrating table for 5 s to 10 s. A part of the slurry that is beyond the mold is scraped off along a top surface of the mold, smoothing is conducted, and the mold is then immediately covered with a polyethylene film to prevent water loss. 24 h later, the mold is removed, and a resulting product is cured in a standard curing room to produce a semi-dogbone-shaped sample with a single steel fiber.

S200: An obtained cured specimen is subjected to electrochemical corrosion tests matched with predetermined different steel fiber corrosion degrees to produce specimens with different corrosion degrees, where each specimen is a semi-dogbone-shaped sample with a single steel fiber embedded.

The electrochemical corrosion tests are testing methods in which varying corrosion degrees are induced for steel fibers through electrochemical reactions to simulate the corrosion conditions in actual environments. A steel fiber corrosion degree refers to an extent to which a steel fiber is corroded. A steel fiber corrosion degree can usually be measured by indexes such as a mass loss rate and a surface morphology change.

It is assumed that the following three different steel fiber corrosion degrees need to be simulated: mild corrosion, moderate corrosion, and severe corrosion. For the mild corrosion, a small current density and a short corrosion time can be set, such as a current density of 0.1 mA/cm² and a corrosion time of 24 h. For the moderate corrosion, the current density and corrosion time can be increased appropriately, such as a current density of 0.5 mA/cm² and a corrosion time of 48 h. For the severe corrosion, the current density can be further increased, and the corrosion time can be further extended, such as a current density of 1 mA/cm² and a corrosion time of 72 h.

S300: A preset uniaxial tensile test is conducted for the specimens with the different corrosion degrees to obtain a load change of each steel fiber during a pull-out process, and interfacial bonding strengths between steel fibers with different corrosion degrees and concretes are analyzed. A preset acid-washing operation is conducted for steel fibers undergoing the preset uniaxial tensile test one by one. Based on a mass change of each steel fiber before and after the preset acid-washing operation, mass loss rates of the steel fibers with the different corrosion degrees are calculated one by one, where a mass loss rate of a steel fiber is defined as corrosion degree data of the steel fiber.

The uniaxial tensile test refers to a test in which a specimen is uniaxially stretched. The uniaxial tensile test is intended to acquire data such as a load change and an interfacial bonding strength for a steel fiber during a pull-out process. The acid-washing operation refers to a process of removing a corrosion layer on a surface of a steel fiber with an acid solution, which facilitates the accurate calculation of a mass loss rate of a steel fiber. An interfacial bonding strength refers to a bonding force between a steel fiber and a concrete. An interfacial bonding strength is an important index for measuring the interfacial bonding performance between a steel fiber and a concrete.

It is assumed that there is a set of semi-dogbone-shaped samples undergoing the electrochemical corrosion tests.

Uniaxial tensile test: A specimen is stretched with a universal testing machine at a loading rate of 1 mm/min. A load change during a pull-out process is recorded. It is found that, as the stretching proceeds, a load gradually increases until a steel fiber is pulled out. According to a load change curve, a maximum load is calculated to be 10 kN. When it is assumed that a cross-sectional area of a steel fiber is 10 mm², an interfacial bonding strength is 10 kN/10 mm²=1 MPa.

Acid-washing operation: Dilute hydrochloric acid is selected as the acid solution. A steel fiber is soaked in the acid solution for 30 min.

A soaked steel fiber is then fully rinsed with clean water. Masses of the steel fiber before and after the acid-washing operation are measured on a precision balance to be 10 g and 9.8 g, respectively.

Mass loss rate: mass loss rate=(10 g−9.8 g)/10 g×100%=2%.

S400: Interfacial bonding strength data corresponding to the different corrosion degrees is fitted by a preset statistical analysis method to produce a mathematical expression between an interfacial bonding strength and a corrosion degree.

A proper statistical analysis method can be selected based on characteristics of the data and a research purpose. For example, if the data presents a linear relationship, the linear regression analysis can be selected. If the data is relatively complex, the non-linear fitting can be tried.

The mathematical expression between an interfacial bonding strength and a corrosion degree is produced through data fitting. Expression form: The mathematical expression can be a functional relationship, such as y=f(x), where y represents an interfacial bonding strength and x represents a corrosion degree.

It is assumed that interfacial bonding strength data between steel fibers with different corrosion degrees and concretes is acquired through the step S300. Details are as follows: When a corrosion degree (mass loss rate) of a steel fiber is 5%, an interfacial bonding strength is 2.5 MPa. When the corrosion degree is 10%, the interfacial bonding strength is 2.2 MPa. When the corrosion degree is 15%, the interfacial bonding strength is 2.0 MPa. When the corrosion degree is 20%, the interfacial bonding strength is 1.8 MPa. When the corrosion degree is 25%, the interfacial bonding strength is 1.6 MPa.

The linear regression analysis can be conducted with a data analysis tool in Excel. The corrosion degree and interfacial bonding strength data is first input into an Excel spreadsheet. Then, “Data Analysis” under a “Data” tab is selected, and “Regression” in a pop-up dialog box is selected. An input region and an output region are set, and “OK” is clicked for analysis. A fitting process is as follows: The linear regression analysis is conducted to produce a fitting line with an equation of y=−0.03x+2.65, where y represents an interfacial bonding strength and x represents a corrosion degree (mass loss rate). A goodness of fit R² is 0.95, indicating a prominent fitting effect. Mathematical expression: The mathematical expression between an interfacial bonding strength and a corrosion degree is y=−0.03x+2.65. This expression can be used to predict interfacial bonding strengths between steel fibers with different corrosion degrees and concretes.

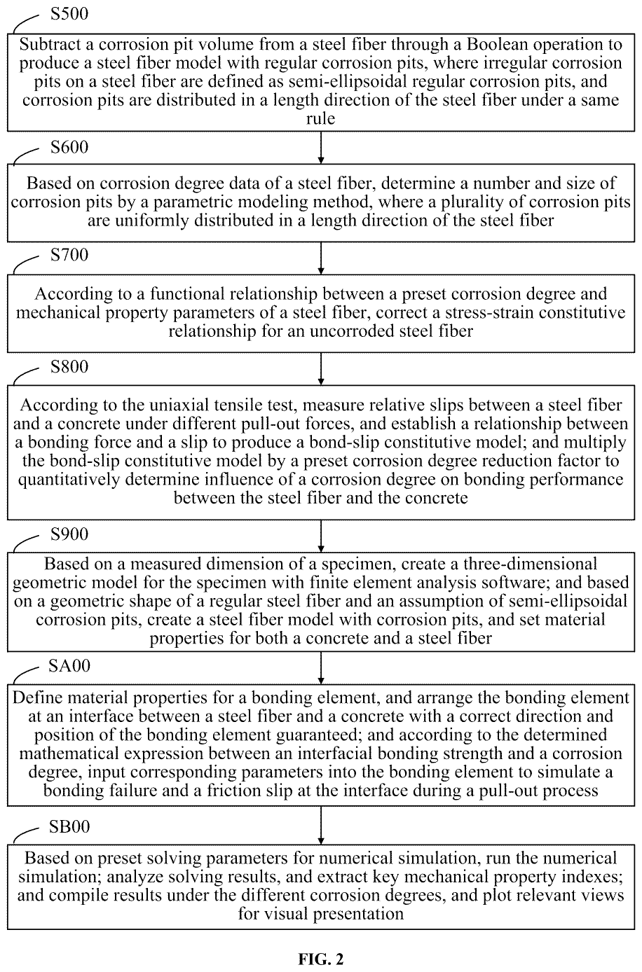

As shown in FIG. 2, the characterization method for influence of a corrosion degree on interfacial bonding performance between a steel fiber and a concrete further includes steps in parallel with the fitting interfacial bonding strength data corresponding to the different corrosion degrees by a preset statistical analysis method to produce a mathematical expression between an interfacial bonding strength and a corrosion degree, where the steps are specifically as follows:

S500: A corrosion pit volume is subtracted from a steel fiber through a Boolean operation to produce a steel fiber model with regular corrosion pits. Irregular corrosion pits on a steel fiber are defined as semi-ellipsoidal regular corrosion pits, and corrosion pits are distributed in a length direction of the steel fiber under a same rule.

The reason to define irregular corrosion pits on a steel fiber as semi-ellipsoidal regular corrosion pits and assume that corrosion pits are distributed in a length direction of the steel fiber under a same rule is as follows: Since pit-like corrosion affects the degradation of mechanical properties of a steel fiber more significantly than uniform corrosion, the influence of corrosion pits can be primarily considered at a rough simulation stage. In order to improve the calculation efficiency, the following assumptions are made: a) In view of the significant discreteness of corrosion pit shapes, irregular corrosion pits of a steel fiber are simplified as semi-ellipsoidal regular corrosion pits. b) Given the random distribution of corrosion pits on a steel fiber, it is assumed during the rough simulation that corrosion pits are distributed in a length direction of the steel fiber under a same rule.

The Boolean operation is an operation commonly adopted for three-dimensional modeling. In the Boolean operation, a new shape is created by subtracting one entity from another entity.

The steel fiber model with regular corrosion pits is a steel fiber model with the defined semi-ellipsoidal regular corrosion pits produced after the processing of the Boolean operation.

S600: Based on corrosion degree data of a steel fiber, a number and size of corrosion pits are determined by a parametric modeling method. A plurality of corrosion pits are uniformly distributed in a length direction of the steel fiber.

The “parametric modeling method” is a modeling technique that controls a shape and size of a model by defining parameters. In this step, based on a corrosion degree of a steel fiber, a number and size of corrosion pits are determined.

A number and size of corrosion pits refer to a number of corrosion pits on a steel fiber and dimension parameters for each corrosion pit, such as semi-major axis, semi-minor axis, and depth. These parameters will vary with a corrosion degree of a steel fiber.

The phrase “a plurality of corrosion pits are uniformly distributed in a length direction of the steel fiber” means that a determined number of corrosion pits with a determined size are uniformly arranged in the length direction of the steel fiber to simulate the actual corrosion conditions.

S700: According to a functional relationship between a preset corrosion degree and mechanical property parameters of a steel fiber, a stress-strain constitutive relationship for an uncorroded steel fiber is corrected.

A functional relationship between a corrosion degree and mechanical property parameters of a steel fiber is a mathematical relationship between the corrosion degree and the mechanical property parameters (such as elastic modulus and yield strength) for the steel fiber. Through this functional relationship, mechanical property parameters of a steel fiber can be corrected according to a corrosion degree of the steel fiber. With this functional relationship, mechanical property tests can be conducted for steel fibers with different corrosion degrees, such as a tensile test and a bending test, so as to acquire data on how mechanical property parameters of a steel fiber change with a corrosion degree. The functional relationship between a corrosion degree and mechanical property parameters is established through data fitting.

A process for correcting the stress-strain constitutive relationship for an uncorroded steel fiber is specifically as follows: 1. Determination of a correction method: An appropriate correction method is selected based on the functional relationship between a corrosion degree and mechanical property parameters of a steel fiber. The common correction method includes a direct correction method, an equivalent damage method, etc. 2. Correction calculation: Mechanical property parameters in the stress-strain constitutive relationship for an uncorroded steel fiber are corrected based on a corrosion degree according to the selected correction method, so as to obtain a corrected stress-strain constitutive relationship.

It is assumed that, through experimental research, a functional relationship between a corrosion degree and an elastic modulus for a steel fiber is obtained as follows: E=E₀×(1−k×corrosion degree), where E represents an elastic modulus of a corroded steel fiber, E₀ represents an elastic modulus of an uncorroded steel fiber, k is a constant, and the corrosion degree is a mass loss rate.

For an uncorroded steel fiber, a stress-strain constitutive relationship is as follows: σ=E₀×ε, where σ represents a stress and ε represents a strain.

It is necessary to correct the constitutive relationship for an uncorroded steel fiber to consider the influence of corrosion. When it is assumed that a corrosion degree of a steel fiber is 20%, then according to the above functional relationship, an elastic modulus of a corroded steel fiber is as follows: E=E₀×(1−k×0.2).

A corrected stress-strain constitutive relationship is as follows: σ=E×ε=E₀×(1−k×0.2)×ε.

S800: According to the uniaxial tensile test, relative slips between a steel fiber and a concrete under different pull-out forces are measured, and a relationship between a bonding force and a slip is established to produce a bond-slip constitutive model. The bond-slip constitutive model is multiplied by a preset corrosion degree reduction factor to quantitatively determine influence of a corrosion degree on bonding performance between the steel fiber and the concrete.

A relative slip refers to a relative displacement between a steel fiber and a concrete under an action of a force during the uniaxial tensile test. The relationship between a bonding force and a slip is used to describe how a bonding force between a steel fiber and a concrete changes with a relative slip. The bond-slip constitutive model is a mathematical model to characterize a bond-slip behavior between a steel fiber and a concrete. The corrosion degree reduction factor is a coefficient determined based on a corrosion degree of a steel fiber. The corrosion degree reduction factor is used to adjust the bond-slip constitutive model to reflect the influence of corrosion on the bonding performance between a steel fiber and a concrete.

It is assumed that relative slip data between a steel fiber and a concrete under different pull-out forces is acquired through the uniaxial tensile test. For example, when a pull-out force is 10 kN, a relative slip is 0.1 mm. When a pull-out force is 20 kN, a relative slip is 0.2 mm. When a pull-out force is 30 kN, a relative slip is 0.3 mm. When a pull-out force is 40 kN, a relative slip is 0.4 mm. When a pull-out force is 50 kN, a relative slip is 0.5 mm.

Through curve fitting for the data, the relationship between a bonding force and a slip can be determined as follows: F=100 s, where F represents a bonding force (kN) and s represents a relative slip (mm).

Based on this relationship, a linear bond-slip constitutive model can be established. It is assumed that a bond-slip constitutive model when there is no corrosion is F=kos, where ko is a bonding stiffness coefficient when there is no corrosion.

Given the impact of corrosion, it is assumed that, when a corrosion degree is determined to be 20% through experimental research, a corrosion degree reduction factor is 0.8. Thus, a bond-slip constitutive model after corrosion is F=0.8kos.

S900: Based on a measured dimension of a specimen, a three-dimensional geometric model for the specimen is created with finite element analysis software. Based on a geometric shape of a regular steel fiber and an assumption of semi-ellipsoidal corrosion pits, a steel fiber model with corrosion pits is created, and material properties for both a concrete and a steel fiber are set.

A measured dimension of a specimen refers to dimensions of a concrete specimen actually manufactured and a steel fiber. The material properties for a concrete refer to mechanical property parameters of the concrete, such as elastic modulus, Poisson's ratio, and compressive strength.

The material properties for a steel fiber refer to mechanical property parameters of the steel fiber, such as elastic modulus and yield strength.

SA00: Material properties for a bonding element are defined, and the bonding element is arranged at an interface between a steel fiber and a concrete with a correct direction and position of the bonding element guaranteed. According to the determined mathematical expression between an interfacial bonding strength and a corrosion degree, corresponding parameters are input into the bonding element to simulate a bonding failure and a friction slip at the interface during a pull-out process.

The bonding element is a specific element type used in finite element simulation to simulate the interfacial bonding performance between a steel fiber and a concrete, and can reflect characteristics such as bonding force and friction slip at an interface. The material properties refer to mechanical property parameters of the bonding element, such as bonding strength and stiffness. The bonding failure and the friction slip are two major phenomena that may occur at an interface during a pull-out process of a steel fiber. The bonding failure indicates the loss of a bonding force at an interface. The friction slip indicates a relative movement between a steel fiber and a concrete.

It is assumed that, if the simulation is conducted with finite element analysis software, there is a bonding element type exclusively for simulating the interfacial bonding in the finite element analysis software.

Bonding element selection: In the software, a bonding element suitable for simulating an interface between a steel fiber and a concrete is selected, such as an element with specific bonding strength and stiffness parameters.

Material property determination: Through experiments, it is determined that an interfacial bonding strength between a steel fiber and a concrete when there is no corrosion is 5 MPa. The interfacial bonding strength gradually decreases with the increase in a corrosion degree. It is assumed that, through statistical analysis, the mathematical expression between an interfacial bonding strength and a corrosion degree (represented by a mass loss rate) is determined as follows: bonding strength-corrosion degree. According to this expression and the known corrosion degrees, bonding strength parameters of the bonding element at different corrosion degrees are determined. Moreover, based on empirical or theoretical analysis, other material properties of the bonding element are determined, such as stiffness.

Bonding element arrangement: An interface between a steel fiber and a concrete is accurately located in a finite element model. The bonding element is arranged at the interface with a direction of the bonding element consistent with an axial direction of the steel fiber to correctly simulate an interfacial behavior during a pull-out process.

Parameter input: Based on the determined mathematical expression between an interfacial bonding strength and a corrosion degree, corresponding parameters are input into the bonding element. For example, when a corrosion degree is 20%, a bonding strength is calculated to be 5×(1 −0.2× 20%)=4 MPa, and this value is input into the bonding element as a bonding strength parameter.

Bonding failure and friction slip simulation: Parameters of the bonding element, such as friction coefficient, are set to simulate a friction slip behavior. During a simulation process, a stress change and a displacement at the interface are observed. If a stress exceeds a bonding strength, the bonding failure may occur. In addition, with the pull-out of a steel fiber, a relative slip, namely, a friction slip, will occur at the interface.

SB00: Based on preset solving parameters for numerical simulation, the numerical simulation is run. Solving results are analyzed, and key mechanical property indexes are extracted. Results under the different corrosion degrees are compiled, and relevant views are plotted for visual presentation.

The solving parameters for the numerical simulation refer to a set of parameters required for finite element analysis, including a solver algorithm, a time increment, and a convergence criterion. These parameters determine the accuracy and efficiency of simulation. The mechanical property indexes refer to various parameters that are acquired through the numerical simulation and reflect the interfacial bonding performance between a steel fiber and a concrete, such as bonding strength, slip, and stress distribution. The plotting relevant views for visual presentation is as follows: with a visualization function of drawing software or finite element analysis software, numerical simulation results are presented in graphic forms, such as stress cloud maps and displacement vector maps, which facilitates the intuitive comprehension and analysis of results.

It is assumed that the numerical simulation is conducted for interfaces between steel fibers with different corrosion degrees and concretes. For example, when a corrosion degree is 5%, a bonding strength extracted from an output result of the finite element analysis software is 2.8 MPa, and a slip is 0.15 mm. When the corrosion degree is 10%, the bonding strength is 2.5 MPa, and the slip is 0.2 mm. When the corrosion degree is 15%, the bonding strength is 2.2 MPa, and the slip is 0.25 mm. When the corrosion degree is 20%, the bonding strength is 2.0 MPa, and the slip is 0.3 mm.

It is found through regression analysis that the bonding strength decreases linearly with the increase in the corrosion degree, while the slip gradually increases with the increase in the corrosion degree.

Line charts illustrating how the bonding strength and slip vary with the corrosion degree are plotted with drawing software to intuitively demonstrate change laws of the bonding strength and slip. Stress cloud maps under different corrosion degrees are generated in the finite element analysis software to observe a stress distribution at an interface between a steel fiber and a concrete.

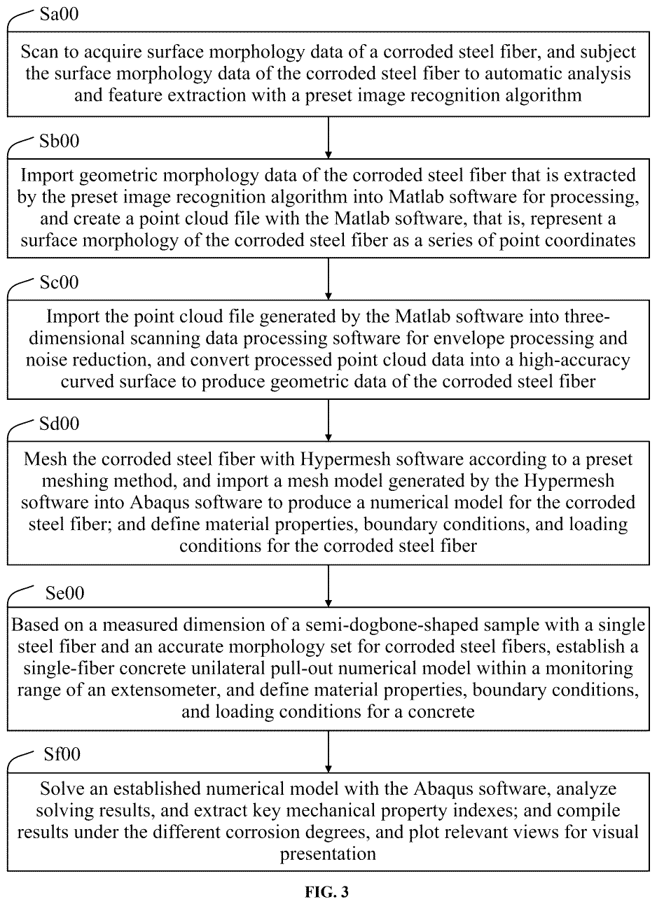

As shown in FIG. 3, the characterization method for influence of a corrosion degree on interfacial bonding performance between a steel fiber and a concrete further includes steps in parallel with the fitting interfacial bonding strength data corresponding to the different corrosion degrees by a preset statistical analysis method to produce a mathematical expression between an interfacial bonding strength and a corrosion degree, where the steps are specifically as follows:

Sa00: Scanning is conducted to acquire surface morphology data of a corroded steel fiber, and the surface morphology data of the corroded steel fiber is subjected to automatic analysis and feature extraction with a preset image recognition algorithm.

The surface morphology data of the corroded steel fiber refers to feature information of a surface of the corroded steel fiber, such as a shape, a texture, and a roughness, and can be acquired by a scanning device.

The image recognition algorithm is an algorithm capable of automatically identifying and analyzing a target in an image. The image recognition algorithm is used here to process the surface morphology data of the corroded steel fiber to extract feature information. The common image recognition algorithm includes convolutional neural network (CNN), support vector machine (SVM), Hough Transform, etc.

It is assumed that surface morphology analysis needs to be conducted for a group of corroded steel fibers.

Surface morphology data of the corroded steel fibers is acquired as follows: The entire surface of each corroded steel fiber is scanned with a three-dimensional scanner at a scanning resolution of 0.1 mm. Data obtained after the scanning is pre-processed to remove noise and correct a color, so as to obtain a clear image for a surface morphology of a steel fiber.

Image recognition algorithm selection: Given the complexity of a surface morphology of a steel fiber, CNN is selected as the image recognition algorithm. Training data is prepared, and some corrosion features on a surface of a steel fiber are manually annotated, such as corrosion area, corrosion depth, and corrosion shape.

Automatic analysis and feature extraction: Feature parameters to be extracted are defined as a corrosion area, a corrosion depth, and a corrosion shape, respectively. An image of a surface morphology of a steel fiber is analyzed with a trained CNN algorithm to extract feature parameters such as corrosion area, corrosion depth, and corrosion shape.

For example, it is determined through analysis that a steel fiber has a corrosion area of 10 mm², a corrosion depth of 0.5 mm, and an irregular ellipsoidal corrosion shape.

Sb00: Geometric morphology data of the corroded steel fiber that is extracted by the preset image recognition algorithm is imported into Matlab software for processing, and a point cloud file is created with the Matlab software, that is, a surface morphology of the corroded steel fiber is represented as a series of point coordinates.

The Matlab software is powerful mathematical computing and data analysis software that can be used for tasks such as data processing, modeling, and visualization. The point cloud file is a file composed of a dataset of a series of point coordinates representing a surface of an object, and is used to describe a shape of an object.

Sc00: The point cloud file generated by the Matlab software is imported into three-dimensional scanning data processing software for envelope processing and noise reduction, and processed point cloud data is converted into a high-accuracy curved surface to produce geometric data of the corroded steel fiber.

The envelope processing refers to processing the point cloud data to determine an external contour of an object and remove redundant points, thereby making the point cloud data concisely and accurately represent a shape of the object. The noise reduction is intended to remove noise points from the point cloud data to improve the quality and accuracy of the data. Noise may come from factors such as errors and environmental interference during a scanning process. The high-accuracy curved surface refers to a smooth curved surface obtained by fitting and reconstructing the processed point cloud data. The high-accuracy curved surface can accurately represent a geometric shape of the corroded steel fiber.

The three-dimensional scanning data processing software can be powerful three-dimensional scanning data processing software, such as GeomagicWrap and PolyWorks. These types of software typically offer abundant point cloud processing tools and functions.

Sd00: The corroded steel fiber is meshed with Hypermesh software according to a preset meshing method, and a mesh model generated by the Hypermesh software is imported into Abaqus software to produce a numerical model for the corroded steel fiber. Material properties, boundary conditions, and loading conditions for the corroded steel fiber are defined.

The Hypermesh software is professional finite-element pre-processing software. The Hypermesh software is used for meshing and optimizing a geometric model to provide a high-quality mesh model for the subsequent numerical simulation. The preset meshing method is a meshing strategy preset based on the characteristics of a research object and the requirements of numerical simulation, including the selection of a mesh type, size, density, etc. The meshing refers to the discretization of a geometric model into a plurality of small elements to enable the computation and analysis in numerical simulation. The Abaqus software is finite element analysis software widely used for numerical simulation and analysis of various engineering problems. The material properties refer to parameters characterizing the mechanical properties of a material, such as elastic modulus, Poisson's ratio, and yield strength. The boundary conditions refer to physical conditions prescribed for a boundary of a model during numerical simulation, such as displacement constraint and force loading. The loading conditions refer to external forces or loading conditions applied to a model during numerical simulation, such as pull-out force and pressure.

Se00: Based on a measured dimension of a semi-dogbone-shaped sample with a single steel fiber and an accurate morphology set for corroded steel fibers, a single-fiber concrete unilateral pull-out numerical model within a monitoring range of an extensometer is established, and material properties, boundary conditions, and loading conditions for a concrete are defined.

The extensometer is an instrument for measuring a deformation of an object. The “monitoring range of an extensometer” here refers to an effective measurement range of the extensometer determined in the numerical model.

The “single-fiber concrete unilateral pull-out numerical model” refers to a model that is established by a numerical simulation method and simulates a process of pulling a single steel fiber out from a concrete unilaterally.

It is assumed that a measured dimension of the semi-dogbone-shaped sample with a single steel fiber is as follows: the concrete specimen has a length of 100 mm, a width of 50 mm, and a height of 50 mm, and the steel fiber has a length of 30 mm and is embedded into a concrete at a depth of 20 mm. The accurate morphology set for corroded steel fibers is obtained through the previous steps.

Numerical model establishment: With the Abaqus software, geometric shapes of the concrete specimen and the steel fiber are constructed based on measured dimensions. The concrete specimen may be represented as a rectangular solid, and the steel fiber can be represented as a cylinder. The model is meshed, and an appropriate element type and mesh size are selected.

Definition of concrete material properties: It is determined through tests that the concrete has an elastic modulus of 30 GPa, a Poisson's ratio of 0.2, and a compressive strength of 30 MPa. In the Abaqus software, these parameters are input into the definition for the concrete material.

Setting of boundary conditions and loading conditions: Fixed constraints are set at a bottom of the concrete specimen to simulate a fixed state of the concrete specimen during testing. An increasing pull-out force is applied to an end of the steel fiber to simulate a loading process of a unilateral pull-out test. It is assumed that the pull-out force starts from 0 and increases at a rate of 1 kN/s.

Through the above steps, the single-fiber concrete unilateral pull-out numerical model within the monitoring range of the extensometer is established, and the material properties, boundary conditions, and loading conditions for the concrete are defined, which gets ready for the subsequent numerical simulation analysis.

Sf00: An established numerical model is solved with the Abaqus software, solving results are analyzed, and key mechanical property indexes are extracted. Results under the different corrosion degrees are compiled, and relevant views are plotted for visual presentation.

It is assumed that single-fiber concrete unilateral pull-out numerical models under different corrosion degrees have been constructed, and solved in the Abaqus software. A specific operation process for the step Sf00 is as follows:

The solving is conducted in the Abaqus software with solving parameters set as follows: static analysis, a time increment: 0.1 s, and a convergence criterion: a residual error<1e-5. A solving task is submitted to make the Abaqus software perform a computation on the numerical model.

Extraction of solving results: After the numerical model is solved, a post-processing module of the Abaqus software is opened, and stress, strain, and displacement data in a result file is viewed. Stress and displacement data at an interface between a steel fiber and a concrete is extracted from the result file.

Calculation of key mechanical property indexes: A bonding strength is defined as a maximum shearing stress at an interface, and a slip is defined as a displacement of a steel fiber in a pull-out direction. Based on the extracted stress and displacement data, bonding strengths and slips under different corrosion degrees are calculated. For example, when a corrosion degree is 5%, a bonding strength is calculated to be 2.8 MPa, and a slip is calculated to be 0.15 mm. When the corrosion degree is 10%, the bonding strength is calculated to be 2.5 MPa, and the slip is calculated to be 0.2 mm. When the corrosion degree is 15%, the bonding strength is calculated to be 2.2 MPa, and the slip is calculated to be 0.25 mm. When the corrosion degree is 20%, the bonding strength is calculated to be 2.0 MPa, and the slip is calculated to be 0.3 mm.

Compiling of results under different corrosion degrees: It is found through regression analysis that the bonding strength decreases linearly with the increase in the corrosion degree, while the slip gradually increases with the increase in the corrosion degree.

Plotting of relevant views for visual presentation: Line charts illustrating how the bonding strength and slip vary with the corrosion degree are plotted with the Matlab software to intuitively demonstrate change laws of the bonding strength and slip. Stress cloud maps under different corrosion degrees are generated in the Abaqus software to observe a stress distribution at an interface between a steel fiber and a concrete.

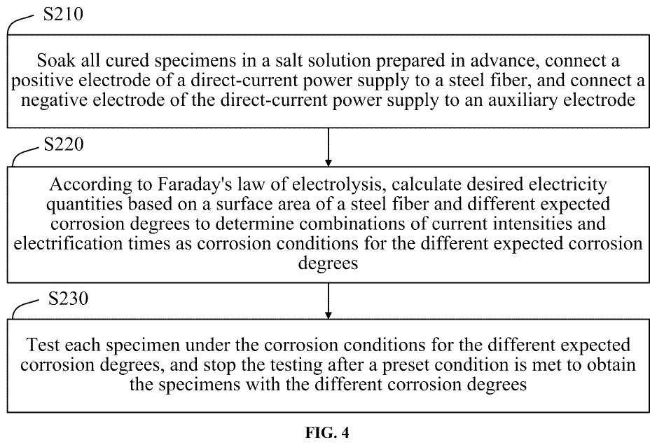

As shown in FIG. 4, the subjecting an obtained cured specimen to electrochemical corrosion tests matched with predetermined different steel fiber corrosion degrees to produce specimens with different corrosion degrees includes:

S210: All cured specimens are soaked in a salt solution prepared in advance, a positive electrode of a direct-current power supply is connected to a steel fiber, and a negative electrode of the direct-current power supply is connected to an auxiliary electrode.

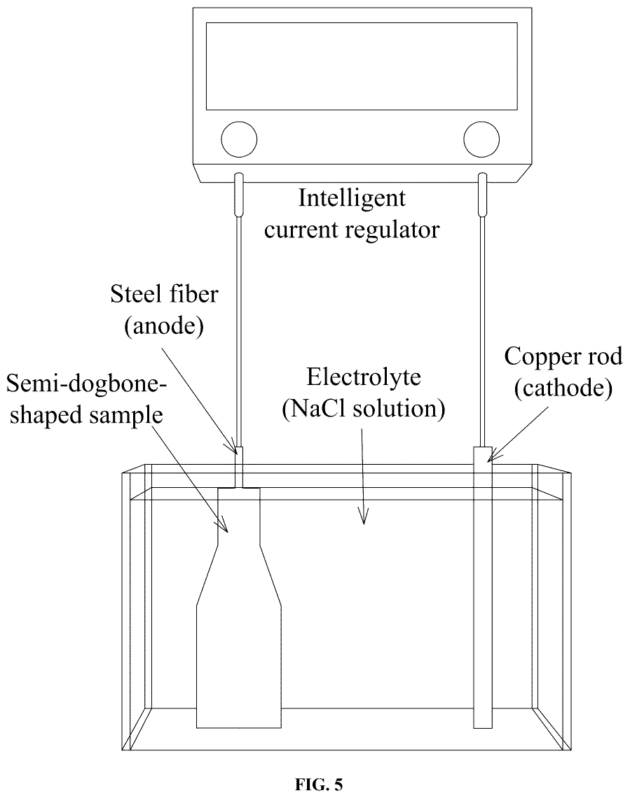

The step S210 can refer to FIG. 5.

The salt solution refers to a solution with a specific salt for an electrochemical corrosion test. The salt solution is usually a corrosive medium to simulate an actual environment. The direct-current power supply is a device for supplying a direct current. The direct-current power supply is used to form an electric field during an electrochemical corrosion test. The connection of a positive electrode to a steel fiber refers to an electrical connection of a positive electrode of a direct-current power supply to a steel fiber in a specimen.

S220: According to Faraday's law of electrolysis, desired electricity quantities are calculated based on a surface area of a steel fiber and different expected corrosion degrees to determine combinations of current intensities and electrification times as corrosion conditions for the different expected corrosion degrees.

The Faraday's law of electrolysis describes a relationship between an amount of substance deposited at an electrode and a quantity of electricity passed through the electrode during electrolysis. The different expected corrosion degrees refer to preset corrosion degrees for steel fibers to achieve.

The combinations of current intensities and electrification times are determined as follows: current intensities are combined with electrification times to determine the corrosion conditions for the different expected corrosion degrees. For example, if mild corrosion needs to be achieved, a low current intensity and a short electrification time can be selected. If severe corrosion needs to be achieved, a high current intensity and a long electrification time can be selected. Through a plurality of tests, corrosion conditions are continuously optimized to improve the accuracy and reliability of an experiment. A combination of a current intensity and an electrification time can be adjusted according to an experimental result.

S230: Each specimen is tested under the corrosion conditions for the different expected corrosion degrees, and the testing is stopped after a preset condition is met to obtain the specimens with the different corrosion degrees.

The preset condition can be a corrosion degree index or a time limit. The corrosion degree index is used to determine whether a test has achieved the preset condition, and includes a mass loss rate, a surface morphology change, etc. A relationship between different corrosion degree indexes and specimen performance can be determined through experimental or theoretical analysis, so as to reasonably set the preset condition. Time limit: In addition to the corrosion degree index, a time limit for a test can be set. If a preset corrosion degree cannot be achieved within a specified time, corrosion conditions can be adjusted or a test time can be extended based on an actual situation. After the specimens with the different corrosion degrees are obtained, these specimens also need to be classified and labeled based on the corrosion degrees for subsequent analysis and research. The specimens with the different corrosion degrees can be distinguished through different colors, numbers, labels, etc.

For example, during an actual operation, after being cured for 14 d, a specimen is taken out from a curing environment and soaked in a NaCl solution with a mass fraction of 3.5%. After the soaking is completed, a positive electrode of a direct-current power supply is connected to a steel fiber, a negative electrode of the direct-current power supply is connected to a copper rod, and a current is set to 5 mA. According to Faraday's law of electrolysis, a corrosion degree of a steel fiber can be controlled by adjusting an electrification time. 30 specimens are prepared in total and divided into 5 groups, including a control group without an electrification treatment, and four experimental groups with electrification times of 80 min, 160 min, 240 min, and 320 min, respectively, with 6 specimens in each group.

The characterization method for influence of a corrosion degree on interfacial bonding performance between a steel fiber and a concrete further includes steps between the testing each specimen under the corrosion conditions for the different expected corrosion degrees and the stopping the testing after a preset condition is met, where the steps are specifically as follows:

S2a0: During a corrosion process, an electrochemical impedance spectroscopy monitoring device is started to monitor and acquire electrochemical impedance spectroscopy data, and resistance and capacitance parameters are extracted from the electrochemical impedance spectroscopy data. An electrochemical noise monitoring device is synchronously started to acquire electrochemical noise data, and a noise amplitude is extracted from the electrochemical noise data.

The electrochemical impedance spectroscopy monitoring device is an instrument for measuring impedance characteristics of an electrochemical system. By applying a small-amplitude alternate-current signal and measuring a response of a system, the electrochemical impedance spectroscopy monitoring device acquires electrochemical impedance spectroscopy data. The electrochemical noise monitoring device is an instrument for measuring small fluctuations in a current and a voltage that naturally occur in an electrochemical system, namely, electrochemical noise data.

The analysis of resistance and capacitance parameters can be as follows: the resistance and capacitance parameters are extracted by an appropriate method based on characteristics of electrochemical impedance spectroscopy. For example, resistance and capacitance values can be determined by fitting an equivalent circuit model.

The analysis of a noise amplitude can be conducted as follows: electrochemical noise data is analyzed with data analysis software to extract a noise amplitude parameter. The noise amplitude can be determined by calculating a standard deviation, peak value, etc. of a noise.

S2b0: Comprehensive corrosion index values at different time points are calculated according to a preset comprehensive corrosion index calculation method, and a change curve of a comprehensive corrosion index over time is plotted.

The comprehensive corrosion index calculation method is a calculation method for comprehensive assessment of a corrosion degree of a steel fiber, and usually combines a plurality of electrochemical parameters.

It is assumed that parameters such as resistance, capacitance, and noise amplitude have been obtained in the step S2a0. Accordingly, the operation in the step S260 is conducted as follows:

Determination of the comprehensive corrosion index calculation method: Resistance, capacitance, and a noise amplitude are selected as parameters for calculating a comprehensive corrosion index. Based on empirical and theoretical analysis, weights for the resistance, the capacitance, and the noise amplitude are determined to be 0.4, 0.3, and 0.3, respectively. A formula for calculating a comprehensive corrosion index is established as follows: comprehensive corrosion index=0.4×resistance+0.3×capacitance+0.3×noise amplitude.

The different time points are determined as follows: A time interval for monitoring a comprehensive corrosion index is set to once every hour. During a corrosion test, a time point at each hour is recorded.

Plotting of a change curve of a comprehensive corrosion index over time: With a time as an x-coordinate and a comprehensive corrosion index as a y-coordinate, the change curve is plotted to intuitively demonstrate a trend of a corrosion degree to change over time.

S2c0: According to the change curve of a comprehensive corrosion index over time, a comprehensive corrosion index change efficiency is determined.

The comprehensive corrosion index change efficiency is used to measure a rate at which a corrosion degree of a steel fiber changes over time. The comprehensive corrosion index change efficiency is typically determined by calculating a ratio of a change of a comprehensive corrosion index within a specified time range to a time span.

It is assumed that the change curve of a comprehensive corrosion index over time is obtained through the step S2b0. For example, at the beginning, a comprehensive corrosion index is relatively low. The comprehensive corrosion index gradually increases over time. After a period of monitoring, it is found that the comprehensive corrosion index increases slowly within the first few hours, but the growth of the comprehensive corrosion index is accelerated in the subsequent time period.

Start and end time points are selected to calculate the comprehensive corrosion index change efficiency. It is assumed that a comprehensive corrosion index value at a start time point is 50, and after a specified period of time, a comprehensive corrosion index value at an end time point is 80, with a time span of 6 h between these two time points.

In this case, a comprehensive corrosion index change is 80−50=30 and a comprehensive corrosion index change efficiency is 30−6=5.

S2d0: An adjustment plan for corrosion conditions of an expected corrosion degree is determined based on a correspondence between a range of the comprehensive corrosion index change efficiency and the adjustment plan for the corrosion conditions of the expected corrosion degree, and the adjustment plan for the corrosion conditions of the expected corrosion degree is implemented.

The adjustment plan refers to a specific method for adjusting corrosion conditions of an expected corrosion degree based on the range of the comprehensive corrosion index change efficiency.

Plan formulation: A respective adjustment plan for corrosion conditions is formulated for different ranges. For example, if the comprehensive corrosion index change efficiency is in a low-efficiency range, it may be considered to increase a current intensity or extend an electrification time. If the comprehensive corrosion index change efficiency is in a high-efficiency range, it may be considered to appropriately reduce a current intensity or shorten an electrification time to control the development of a corrosion degree.

Based on the formulation of the range and the adjustment plan, a correspondence between the range of the comprehensive corrosion index change efficiency and the adjustment plan for corrosion conditions of an expected corrosion degree is established. This correspondence can be represented in a form of a table, a chart, or an algorithm to facilitate the rapid determination of an adjustment plan in an actual experiment.

It is assumed that the comprehensive corrosion index change efficiency is determined to be 5% per hour through the step S2c0. According to empirical and theoretical analysis, the following ranges are classified for the comprehensive corrosion index change efficiency: low-efficiency range: less than or equal to 3% per hour; medium-efficiency range: greater than 3% per hour and less than or equal to 7% per hour; and high-efficiency range: greater than 7% per hour.

For a test expecting a moderate corrosion degree, corrosion conditions are initially set as follows: a current intensity is 0.5 A and an electrification time is 10 h. If the comprehensive corrosion index change efficiency is in the low-efficiency range, a current intensity can increase to 0.7 A while an electrification time remains unchanged. If the comprehensive corrosion index change efficiency is in the high-efficiency range, a current intensity can be reduced to 0.3 A, or an electrification time can be shortened to 8 h.

During an actual experiment, when the comprehensive corrosion index change efficiency is determined to be 5% per hour, which is in the medium-efficiency range, the current corrosion conditions can remain unchanged, and the experimental observation is continued. If the comprehensive corrosion index change efficiency exceeds the medium-efficiency range during the subsequent monitoring, then a corresponding adjustment plan is determined based on a correspondence and implemented.

The conducting a preset uniaxial tensile test for the specimens with the different corrosion degrees to obtain a load change of each steel fiber during a pull-out process, and analyzing interfacial bonding strengths between steel fibers with different corrosion degrees and concretes includes:

S310: A semi-dogbone-shaped sample is arranged in a fixture of an electronic universal testing machine.

The fixture is arranged on the electronic universal testing machine. The fixture is a device for fixing a specimen to ensure that the specimen does not loosen or fall off during a test.

S320: The electronic universal testing machine is started, a pull-out test is conducted under crosshead displacement control, and experimental data is synchronously acquired. The crosshead displacement control refers to achieving loading of the semi-dogbone-shaped sample by controlling a crosshead movement speed of the electronic universal testing machine. The experimental data includes force, displacement, and deformation data.

The pull-out test is an experimental process of pulling a steel fiber out from a concrete. The pull-out test is conducted to study the interfacial bonding performance between a steel fiber and a concrete.

S330: A pull-out force-displacement curve is plotted according to force and displacement data in the experimental data. Based on the pull-out force-displacement curve, a peak pull-out force is determined, which is a maximum force withstood by the semi-dogbone-shaped sample during the pull-out test. Based on a geometric dimension of the semi-dogbone-shaped sample and an embedding depth parameter of a steel fiber, a contact area between the steel fiber and a concrete is calculated.

S340: The peak pull-out force is divided by the contact area to calculate an interfacial bonding strength.

For example, an electronic universal testing machine, an extensometer, and a dynamic acquisition box are used in combination with a corresponding data acquisition system to conduct a pull-out test under crosshead displacement control at a loading rate of 1.5 mm/min for a semi-dogbone-shaped sample with a single steel fiber, as shown in FIG. 7. 6 samples are tested in each group, and an average is taken. A peak load error of each test should be less than or equal to 10% of an average peak load for each group. The pull-out performance of a steel fiber adopted in this test in a concrete is represented as a pull-out load-displacement curve (P-s curve), where P represents a pull-out force and s represents a displacement. A calculation formula for a bonding strength is as follows:

$${τ}_{a v} = \frac{{P}_{max}}{π \times {d}_{f} \times {L}_{E}} ,$$

where τₐᵥ—bonding strength in a unit of megapascal (MPa);
Pₘₐₓ—maximum pull-out load in a unit of Newton (N);
d_{f}—steel fiber diameter in a unit of millimeter (mm); and
L_{E}—steel fiber embedding depth in a unit of millimeter (mm).

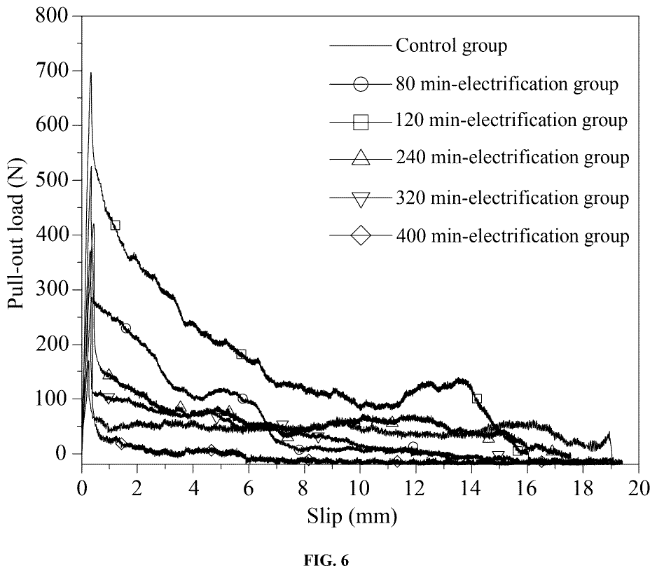

Experimental results are shown in FIG. 6. At an initial stage of stretching, a pull-out load increases rapidly with the increase of a slip. A load at this stage mainly comes from the static friction and adhesion between a straight steel fiber and a concrete. As the load continues to increase, a matrix on a surface of the steel fiber is damaged until the debonding phenomenon occurs. When the tensile load reaches a peak, the dynamic friction between the steel fiber and the matrix channel is dominated, and a specified load is maintained. Finally, as the slip increases, the steel fiber is gradually pulled out, and the load decreases rapidly until disappearing.

The conducting a preset acid-washing operation for steel fibers undergoing the preset uniaxial tensile test one by one, and based on a mass change of each steel fiber before and after the preset acid-washing operation, calculating mass loss rates of the steel fibers with the different corrosion degrees one by one includes: after the preset uniaxial tensile test, each steel fiber is taken out, acid-washed using a hydrochloric acid solution in combination with a corrosion inhibitor to dissolve a corrosion layer on a surface, fully rinsed with deionized water and absolute ethanol, oven-dried, and then weighed with an electronic balance. A post-test mass and a pre-test mass of each steel fiber are compared to calculate a corrosion degree of each steel fiber. The corrosion degree is expressed as a mass loss rate, that is, the corrosion degree=(pre-test mass−post-test mass)/pre-test mass×100%.

The characterization method for influence of a corrosion degree on interfacial bonding performance between a steel fiber and a concrete further includes steps in parallel with the conducting a preset acid-washing operation for steel fibers undergoing the preset uniaxial tensile test one by one, and based on a mass change of each steel fiber before and after the preset acid-washing operation, calculating mass loss rates of the steel fibers with the different corrosion degrees one by one, where the steps are specifically as follows:

SC00: A steel fiber is synchronously scanned by a μ-XCT device at different angles to acquire scanning data at the different angles, and a three-dimensional image of the steel fiber is reconstructed. A gray-scale distribution of the three-dimensional image acquired by μ-XCT scanning is analyzed, and a concrete, the steel fiber, and a corrosion product are distinguished. Surface morphology features of the steel fiber are extracted by a morphological analysis method. Results of gray-scale and morphological analysis are integrated for quantification to obtain a corrosion degree of the steel fiber.

The μ-XCT device is a micro-focus X-ray computed tomography device that can perform high-resolution three-dimensional imaging for an object.

Gray-scale distribution: In an image resulting from μ-XCT scanning, gray-scale values in different regions reflect degrees of X-ray attenuation, and thus can distinguish among different materials.

The morphological analysis method is an analysis method based on a shape and structure of an image, which can be used to extract surface morphology features of a steel fiber.

Integrating results of gray-scale and morphological analysis refers to integrating information resulting from gray-scale analysis and morphological analysis to accurately quantify a corrosion degree of a steel fiber. A process of integrating results of gray-scale and morphological analysis is as follows: Result integration: Results resulting from the gray-scale analysis and morphological analysis are integrated, and information from the two analysis methods is comprehensively considered. The two analysis results can be integrated by an approach such as weighted averaging and logical determination. Corrosion degree quantification: Based on integration results, a corrosion degree of a steel fiber is quantified. A numerical representation of a corrosion degree of a steel fiber can be determined by an approach including an empirical formula, a mathematical model, or statistical analysis. For example, based on the previous research and experimental experience, an empirical formula is established to quantify a corrosion degree of a steel fiber. This formula can be a linear combination or a nonlinear function of a plurality of parameters. For example, it can be assumed that a relationship among a corrosion degree (R), a surface roughness(S), a gray-scale change (G), and a proportion of a corrosion product area (C) is as follows: R=aS+bG+cC+d, where a, b, c, and d are coefficients produced through experimental data fitting.

SD00: The corrosion degree determined based on μ-XCT scanning results is compared with the corrosion degree determined based on the preset acid-washing operation. If a comparison result falls within a preset difference range, an average of the corrosion degrees for the steel fiber that are determined by the above two modes is taken as a corrosion degree of the steel fiber confirmed this time.

The preset difference range refers to a preset difference in an allowable range. The preset difference range is used to determine whether the corrosion degrees obtained by the two modes are relatively consistent.

Comparative calculation: The corrosion degree determined based on μ-XCT scanning results is compared with the corrosion degree determined based on the preset acid-washing operation. A difference, a relative error, etc. between the two corrosion degrees can be calculated to evaluate a comparison result. For example, if the corrosion degree determined based on μ-XCT scanning results is R1 and the corrosion degree determined based on the preset acid-washing operation is R2, then a difference is |R1−R2|, and a relative error is (|R1−R2|/R1)×100%.

SE00: If the comparison result is beyond the preset difference range, condition information with a large error is transmitted to a terminal held by a relevant person in charge.

The terminal held by a relevant person in charge can be a mobile phone, a computer, or other terminal devices.

The characterization method for influence of a corrosion degree on interfacial bonding performance between a steel fiber and a concrete further includes steps in parallel with the comparing the corrosion degree determined based on μ-XCT scanning results and the corrosion degree determined based on the preset acid-washing operation, and if a comparison result falls within a preset difference range, taking an average of the corrosion degrees for the steel fiber that are determined by the above two modes as a corrosion degree of the steel fiber confirmed this time, where the steps are specifically as follows:

A mass loss rate after the preset acid-washing operation, image feature parameters acquired by the μ-XCT scanning, and pull-out load data of the preset uniaxial tensile test are acquired, and a corrosion degree of a steel fiber is determined as a dependent variable.

A multivariable linear regression model is used to establish a relationship model between the corrosion degree of the steel fiber as the dependent variable and the mass loss rate after the preset acid-washing operation, the image feature parameters acquired by the μ-XCT scanning, and the pull-out load data of the preset uniaxial tensile test as independent variables.

In regression analysis, the dependent variable is a variable that is predicted or explained. The dependent variable here refers to the corrosion degree of the steel fiber. In regression analysis, the independent variables are variables to predict or explain the dependent variable. The independent variables here include the mass loss rate after the preset acid-washing operation, the image feature parameters acquired by the μ-XCT scanning, and the pull-out load data of the preset uniaxial tensile test.

The multivariable linear regression model is constructed as follows: Data preparation: Sufficient steel fiber sample data is acquired, including a mass loss rate, μ-XCT image feature parameters, pull-out load data, and a corresponding steel fiber corrosion degree.

Model construction: A regression analysis tool in statistical software or a programming language is used to establish the multivariable linear regression model with a corrosion degree of a steel fiber as a dependent variable and a mass loss rate, μ-XCT image feature parameters, and pull-out load data as independent variables. Model evaluation: The reliability and validity of the model are determined by evaluating a goodness of fit, significance tests, and other indexes of the model.

The model construction is generally conducted as follows: The independent and dependent variables are input into a regression analysis function in the selected tool to establish the multivariable linear regression model. A general form of the model is y=β0+β1×1+β2×2+β3×3+ . . . +ε, where β0 is an intercept, β1, β2, β3, etc. are regression coefficients, and ¿ is an error term.

The model evaluation can be conducted based on a goodness of fit specifically as follows: A common coefficient of determination (R²) is used to evaluate a goodness of fit of the model. A value of R² ranges from 0 to 1. The closer the value of R² is to 1, the better the data fitting of the model. A calculation formula is R²=1−(sum of squared residuals/total sum of squares). For example, when R² of the model is calculated to be 0.85, it indicates that the model can explain 85% of the variation in the dependent variable.

Based on a same inventive concept, an embodiment of the present disclosure provides a characterization system for influence of a corrosion degree on interfacial bonding performance between a steel fiber and a concrete, including a memory, a processor, and a program that is stored in the memory and can be executed by the processor to implement the method shown in any one of FIG. 1 to FIG. 4.

The embodiments of this specific implementation all are preferred embodiments of the present application, but the protection scope of the present application is not limited thereto. Therefore, all equivalent changes made in accordance with the structure, shape, and principle of the present application shall fall within the protection scope of the present application.

What is claimed is:

1. A characterization method for influence of a corrosion degree on interfacial bonding performance between a steel fiber and a concrete, comprising:
for each of a preset number of semi-dogbone-shaped samples, conducting concrete pouring with a single steel fiber embedded at a preset embedding depth, and curing under preset curing conditions;
subjecting an obtained cured specimen to electrochemical corrosion tests matched with predetermined different steel fiber corrosion degrees to produce specimens with different corrosion degrees, wherein the specimens the semi-dogbone-shaped samples with a single steel fiber embedded;
conducting a preset uniaxial tensile test for the specimens with the different corrosion degrees to obtain a load change of each steel fiber during a pull-out process, and analyzing interfacial bonding strengths between steel fibers with different corrosion degrees and concretes; and
conducting a preset acid-washing operation for steel fibers undergoing the preset uniaxial tensile test one by one, and based on a mass change of each steel fiber before and after the preset acid-washing operation, calculating mass loss rates of the steel fibers with the different corrosion degrees one by one, wherein a mass loss rate of a steel fiber is defined as corrosion degree data of the steel fiber; and
fitting interfacial bonding strength data corresponding to the different corrosion degrees by a preset statistical analysis method to produce a mathematical expression between an interfacial bonding strength and a corrosion degree;
further comprising steps in parallel with the fitting interfacial bonding strength data corresponding to the different corrosion degrees by a preset statistical analysis method to produce a mathematical expression between an interfacial bonding strength and a corrosion degree, wherein the steps are specifically as follows:
subtracting a corrosion pit volume from a steel fiber through a Boolean operation to produce a steel fiber model with regular corrosion pits, wherein irregular corrosion pits on a steel fiber are defined as semi-ellipsoidal regular corrosion pits, and corrosion pits are distributed in a length direction of the steel fiber under a same rule;
based on corrosion degree data of a steel fiber, determining a number and size of corrosion pits by a parametric modeling method, wherein a plurality of corrosion pits are uniformly distributed in a length direction of the steel fiber;
according to a functional relationship between a preset corrosion degree and mechanical property parameters of a steel fiber, correcting a stress-strain constitutive relationship for an uncorroded steel fiber;
according to the uniaxial tensile test, measuring relative slips between a steel fiber and a concrete under different pull-out forces, and establishing a relationship between a bonding force and a slip to produce a bond-slip constitutive model; and multiplying the bond-slip constitutive model by a preset corrosion degree reduction factor to quantitatively determine influence of a corrosion degree on bonding performance between the steel fiber and the concrete;
based on a measured dimension of a specimen, creating a three-dimensional geometric model for the specimen with finite element analysis software;
based on a geometric shape of a regular steel fiber and an assumption of semi-ellipsoidal corrosion pits, creating a steel fiber model with corrosion pits, and setting material properties for both a concrete and a steel fiber;
defining material properties for a bonding element, and arranging the bonding element at an interface between a steel fiber and a concrete with a correct direction and position of the bonding element guaranteed; and according to the determined mathematical expression between an interfacial bonding strength and a corrosion degree, inputting corresponding parameters into the bonding element to simulate a bonding failure and a friction slip at the interface during a pull-out process; and
based on preset solving parameters for numerical simulation, running the numerical simulation; analyzing solving results, and extracting key mechanical property indexes; and compiling results under the different corrosion degrees, and plotting relevant views for visual presentation,
wherein the subjecting an obtained cured specimen to electrochemical corrosion tests matched with predetermined different steel fiber corrosion degrees to produce specimens with different corrosion degrees comprises:
soaking the cured specimens in a salt solution prepared in advance, connecting a positive electrode of a direct-current power supply to a steel fiber, and connecting a negative electrode of the direct-current power supply to an auxiliary electrode;
according to Faraday's law of electrolysis, calculating desired electricity quantities based on a surface area of a steel fiber and different expected corrosion degrees to determine combinations of current intensities and electrification times as corrosion conditions for the different expected corrosion degrees; and
testing each specimen under the corrosion conditions for the different expected corrosion degrees, and stopping the testing after a preset condition is met to obtain the specimens with the different corrosion degrees; and
further comprising steps between the testing each specimen under the corrosion conditions for the different expected corrosion degrees and the stopping the testing after a preset condition is met, wherein the steps are specifically as follows:
during a corrosion process, starting an electrochemical impedance spectroscopy monitoring device to monitor and acquire electrochemical impedance spectroscopy data, and extracting resistance and capacitance parameters from the electrochemical impedance spectroscopy data; and synchronously starting an electrochemical noise monitoring device to acquire electrochemical noise data, and extracting a noise amplitude from the electrochemical noise data;
calculating comprehensive corrosion index values at different time points according to a preset comprehensive corrosion index calculation method, and plotting a change curve of a comprehensive corrosion index over time; and establishing a calculation formula for a comprehensive corrosion index as follows: comprehensive corrosion index value=0.4×resistance+0.3×capacitance+0.3×noise amplitude;
according to the change curve of a comprehensive corrosion index over time, determining a comprehensive corrosion index change efficiency; and
determining an adjustment plan for corrosion conditions of an expected corrosion degree based on a correspondence between a range of the comprehensive corrosion index change efficiency and the adjustment plan for the corrosion conditions of the expected corrosion degree, and implementing the adjustment plan for the corrosion conditions of the expected corrosion degree.

2. The characterization method for influence of a corrosion degree on interfacial bonding performance between a steel fiber and a concrete according to claim 1, further comprising steps in parallel with the fitting interfacial bonding strength data corresponding to the different corrosion degrees by a preset statistical analysis method to produce a mathematical expression between an interfacial bonding strength and a corrosion degree, wherein the steps are specifically as follows:
scanning to acquire surface morphology data of a corroded steel fiber, and subjecting the surface morphology data of the corroded steel fiber to automatic analysis and feature extraction with a preset image recognition algorithm;
importing geometric morphology data of the corroded steel fiber that is extracted by the preset image recognition algorithm into Matlab software for processing, and creating a point cloud file with the Matlab software, that is, representing a surface morphology of the corroded steel fiber as a series of point coordinates;
importing the point cloud file generated by the Matlab software into three-dimensional scanning data processing software for envelope processing and noise reduction, and converting processed point cloud data into a high-accuracy curved surface to produce geometric data of the corroded steel fiber;
meshing the corroded steel fiber with Hypermesh software according to a preset meshing method, and importing a mesh model generated by the Hypermesh software into Abaqus software to produce a numerical model for the corroded steel fiber; and defining material properties, boundary conditions, and loading conditions for the corroded steel fiber;
based on a measured dimension of a semi-dogbone-shaped sample with a single steel fiber and an accurate morphology set for corroded steel fibers, establishing a single-fiber concrete unilateral pull-out numerical model within a monitoring range of an extensometer, and defining material properties, boundary conditions, and loading conditions for a concrete; and
solving an established numerical model with the Abaqus software, analyzing solving results, and extracting key mechanical property indexes; and compiling results under the different corrosion degrees, and plotting relevant views for visual presentation.

3. The characterization method for influence of a corrosion degree on interfacial bonding performance between a steel fiber and a concrete according to claim 1, wherein the conducting a preset uniaxial tensile test for the specimens with the different corrosion degrees to obtain a load change of each steel fiber during a pull-out process, and analyzing interfacial bonding strengths between steel fibers with different corrosion degrees and concretes comprises:
arranging a semi-dogbone-shaped sample in a fixture of an electronic universal testing machine;
starting the electronic universal testing machine, conducting a pull-out test under crosshead displacement control, and synchronously acquiring experimental data, wherein the crosshead displacement control refers to achieving loading of the semi-dogbone-shaped sample by controlling a crosshead movement speed of the electronic universal testing machine, and the experimental data comprises force, displacement, and deformation data;
plotting a pull-out force-displacement curve according to force and displacement data in the experimental data, and based on the pull-out force-displacement curve, determining a peak pull-out force, which is a maximum force withstood by the semi-dogbone-shaped sample during the pull-out test; and based on a geometric dimension of the semi-dogbone-shaped sample and an embedding depth parameter of a steel fiber, calculating a contact area between the steel fiber and a concrete; and
dividing the peak pull-out force by the contact area to calculate an interfacial bonding strength.

4. The characterization method for influence of a corrosion degree on interfacial bonding performance between a steel fiber and a concrete according to claim 1, wherein the conducting a preset acid-washing operation for steel fibers undergoing the preset uniaxial tensile test one by one, and based on a mass change of each steel fiber before and after the preset acid-washing operation, calculating mass loss rates of the steel fibers with the different corrosion degrees one by one comprises: after the preset uniaxial tensile test, taking each steel fiber out, and acid-washing the steel fiber using a hydrochloric acid solution in combination with a corrosion inhibitor to dissolve a corrosion layer on a surface to produce an acid-washed steel fiber; fully rinsing the acid-washed steel fiber with deionized water and absolute ethanol to produce a rinsed steel fiber, oven-drying the rinsed steel fiber to produce a dry steel fiber, and weighing the dry steel fiber with an electronic balance; and comparing a post-test mass and a pre-test mass of each steel fiber to calculate a corrosion degree of each steel fiber, wherein the corrosion degree is expressed as a mass loss rate, that is, the corrosion degree=(pre-test mass−post-test mass)/pre-test mass×100%.

5. The characterization method for influence of a corrosion degree on interfacial bonding performance between a steel fiber and a concrete according to claim 4, further comprising steps in parallel with the conducting a preset acid-washing operation for steel fibers undergoing the preset uniaxial tensile test one by one, and based on a mass change of each steel fiber before and after the preset acid-washing operation, calculating mass loss rates of the steel fibers with the different corrosion degrees one by one, wherein the steps are specifically as follows:
synchronously scanning a steel fiber by a micro X-ray computed tomography (μ-XCT) device at different angles to acquire scanning data at the different angles, and reconstructing a three-dimensional image of the steel fiber; analyzing a gray-scale distribution of the three-dimensional image acquired by μ-XCT scanning, and distinguishing among a concrete, the steel fiber, and a corrosion product; extracting surface morphology features of the steel fiber by a morphological analysis method; and integrating results of gray-scale and morphological analysis for quantification to obtain a corrosion degree of the steel fiber;
comparing the corrosion degree determined based on μ-XCT scanning results and the corrosion degree determined based on the preset acid-washing operation, and if a comparison result falls within a preset difference range, taking an average of the corrosion degrees for the steel fiber that are determined by the above two modes as a corrosion degree of the steel fiber confirmed this time; and
if the comparison result is beyond the preset difference range, transmitting condition information with a large error to a terminal held by a relevant person in charge.

6. The characterization method for influence of a corrosion degree on interfacial bonding performance between a steel fiber and a concrete according to claim 5, further comprising steps in parallel with the comparing the corrosion degree determined based on μ-XCT scanning results and the corrosion degree determined based on the preset acid-washing operation, and if a comparison result falls within a preset difference range, taking an average of the corrosion degrees for the steel fiber that are determined by the above two modes as a corrosion degree of the steel fiber confirmed this time, wherein the steps are specifically as follows:
acquiring a mass loss rate after the preset acid-washing operation, image feature parameters acquired by the μ-XCT scanning, and pull-out load data of the preset uniaxial tensile test, and determining a corrosion degree of a steel fiber as a dependent variable; and
using a multivariable linear regression model to establish a relationship model between the corrosion degree of the steel fiber as the dependent variable and the mass loss rate after the preset acid-washing operation, the image feature parameters acquired by the μ-XCT scanning, and the pull-out load data of the preset uniaxial tensile test as independent variables.

7. A characterization system for influence of a corrosion degree on interfacial bonding performance between a steel fiber and a concrete, comprising a memory, a processor, and a program that is stored in the memory and is executable by the processor, wherein when loaded and executed by the processor, the program is able to implement the characterization method for influence of a corrosion degree on interfacial bonding performance between a steel fiber and a concrete according to claim 1.

8. The characterization method for influence of a corrosion degree on interfacial bonding performance between a steel fiber and a concrete according to claim 2, wherein the conducting a preset uniaxial tensile test for the specimens with the different corrosion degrees to obtain a load change of each steel fiber during a pull-out process, and analyzing interfacial bonding strengths between steel fibers with different corrosion degrees and concretes comprises:
arranging a semi-dogbone-shaped sample in a fixture of an electronic universal testing machine;
starting the electronic universal testing machine, conducting a pull-out test under crosshead displacement control, and synchronously acquiring experimental data, wherein the crosshead displacement control refers to achieving loading of the semi-dogbone-shaped sample by controlling a crosshead movement speed of the electronic universal testing machine, and the experimental data comprises force, displacement, and deformation data;
plotting a pull-out force-displacement curve according to force and displacement data in the experimental data, and based on the pull-out force-displacement curve, determining a peak pull-out force, which is a maximum force withstood by the semi-dogbone-shaped sample during the pull-out test; and based on a geometric dimension of the semi-dogbone-shaped sample and an embedding depth parameter of a steel fiber, calculating a contact area between the steel fiber and a concrete; and
dividing the peak pull-out force by the contact area to calculate an interfacial bonding strength.

9. The characterization system for influence of a corrosion degree on interfacial bonding performance between a steel fiber and a concrete according to claim 7, further comprising steps in parallel with the fitting interfacial bonding strength data corresponding to the different corrosion degrees by a preset statistical analysis method to produce a mathematical expression between an interfacial bonding strength and a corrosion degree, wherein the steps are specifically as follows:
scanning to acquire surface morphology data of a corroded steel fiber, and subjecting the surface morphology data of the corroded steel fiber to automatic analysis and feature extraction with a preset image recognition algorithm;
importing geometric morphology data of the corroded steel fiber that is extracted by the preset image recognition algorithm into Matlab software for processing, and creating a point cloud file with the Matlab software, that is, representing a surface morphology of the corroded steel fiber as a series of point coordinates;
importing the point cloud file generated by the Matlab software into three-dimensional scanning data processing software for envelope processing and noise reduction, and converting processed point cloud data into a high-accuracy curved surface to produce geometric data of the corroded steel fiber;
meshing the corroded steel fiber with Hypermesh software according to a preset meshing method, and importing a mesh model generated by the Hypermesh software into Abaqus software to produce a numerical model for the corroded steel fiber; and defining material properties, boundary conditions, and loading conditions for the corroded steel fiber;
based on a measured dimension of a semi-dogbone-shaped sample with a single steel fiber and an accurate morphology set for corroded steel fibers, establishing a single-fiber concrete unilateral pull-out numerical model within a monitoring range of an extensometer, and defining material properties, boundary conditions, and loading conditions for a concrete; and
solving an established numerical model with the Abaqus software, analyzing solving results, and extracting key mechanical property indexes; and compiling results under the different corrosion degrees, and plotting relevant views for visual presentation.

10. The characterization system for influence of a corrosion degree on interfacial bonding performance between a steel fiber and a concrete according to claim 7, wherein the conducting a preset uniaxial tensile test for the specimens with the different corrosion degrees to obtain a load change of each steel fiber during a pull-out process, and analyzing interfacial bonding strengths between steel fibers with different corrosion degrees and concretes comprises:
arranging a semi-dogbone-shaped sample in a fixture of an electronic universal testing machine;
starting the electronic universal testing machine, conducting a pull-out test under crosshead displacement control, and synchronously acquiring experimental data, wherein the crosshead displacement control refers to achieving loading of the semi-dogbone-shaped sample by controlling a crosshead movement speed of the electronic universal testing machine, and the experimental data comprises force, displacement, and deformation data;
plotting a pull-out force-displacement curve according to force and displacement data in the experimental data, and based on the pull-out force-displacement curve, determining a peak pull-out force, which is a maximum force withstood by the semi-dogbone-shaped sample during the pull-out test; and based on a geometric dimension of the semi-dogbone-shaped sample and an embedding depth parameter of a steel fiber, calculating a contact area between the steel fiber and a concrete; and
dividing the peak pull-out force by the contact area to calculate an interfacial bonding strength.

11. The characterization system for influence of a corrosion degree on interfacial bonding performance between a steel fiber and a concrete according to claim 7, wherein the conducting a preset acid-washing operation for steel fibers undergoing the preset uniaxial tensile test one by one, and based on a mass change of each steel fiber before and after the preset acid-washing operation, calculating mass loss rates of the steel fibers with the different corrosion degrees one by one comprises: after the preset uniaxial tensile test, taking each steel fiber out, and acid-washing the steel fiber using a hydrochloric acid solution in combination with a corrosion inhibitor to dissolve a corrosion layer on a surface to produce an acid-washed steel fiber; fully rinsing the acid-washed steel fiber with deionized water and absolute ethanol to produce a rinsed steel fiber, oven-drying the rinsed steel fiber to produce a dry steel fiber, and weighing the dry steel fiber with an electronic balance; and comparing a post-test mass and a pre-test mass of each steel fiber to calculate a corrosion degree of each steel fiber, wherein the corrosion degree is expressed as a mass loss rate, that is, the corrosion degree=(pre-test mass−post-test mass)/pre-test mass×100%.

12. The characterization system for influence of a corrosion degree on interfacial bonding performance between a steel fiber and a concrete according to claim 11, further comprising steps in parallel with the conducting a preset acid-washing operation for steel fibers undergoing the preset uniaxial tensile test one by one, and based on a mass change of each steel fiber before and after the preset acid-washing operation, calculating mass loss rates of the steel fibers with the different corrosion degrees one by one, wherein the steps are specifically as follows:
synchronously scanning a steel fiber by a micro X-ray computed tomography (μ-XCT) device at different angles to acquire scanning data at the different angles, and reconstructing a three-dimensional image of the steel fiber; analyzing a gray-scale distribution of the three-dimensional image acquired by μ-XCT scanning, and distinguishing among a concrete, the steel fiber, and a corrosion product; extracting surface morphology features of the steel fiber by a morphological analysis method; and integrating results of gray-scale and morphological analysis for quantification to obtain a corrosion degree of the steel fiber;
comparing the corrosion degree determined based on μ-XCT scanning results and the corrosion degree determined based on the preset acid-washing operation, and if a comparison result falls within a preset difference range, taking an average of the corrosion degrees for the steel fiber that are determined by the above two modes as a corrosion degree of the steel fiber confirmed this time; and
if the comparison result is beyond the preset difference range, transmitting condition information with a large error to a terminal held by a relevant person in charge.

13. The characterization system for influence of a corrosion degree on interfacial bonding performance between a steel fiber and a concrete according to claim 12, further comprising steps in parallel with the comparing the corrosion degree determined based on μ-XCT scanning results and the corrosion degree determined based on the preset acid-washing operation, and if a comparison result falls within a preset difference range, taking an average of the corrosion degrees for the steel fiber that are determined by the above two modes as a corrosion degree of the steel fiber confirmed this time, wherein the steps are specifically as follows:
acquiring a mass loss rate after the preset acid-washing operation, image feature parameters acquired by the μ-XCT scanning, and pull-out load data of the preset uniaxial tensile test, and determining a corrosion degree of a steel fiber as a dependent variable; and
using a multivariable linear regression model to establish a relationship model between the corrosion degree of the steel fiber as the dependent variable and the mass loss rate after the preset acid-washing operation, the image feature parameters acquired by the μ-XCT scanning, and the pull-out load data of the preset uniaxial tensile test as independent variables.
